(19) United States
(12) Patent Application Publication
(10) Pub. No.: US 2016/0036396 A1
(43) Pub. Date: Feb. 4, 2016

(54) Power Amplifier, and Method of the Same

(71) Applicant: Beken Corporation, Shanghai (CN)

(72) Inventors: Yunfeng Chen, Shanghai (CN); Dawei Guo, Shanghai (CN); Peng Han, Shanghai (CN)

(73) Assignee: Beken Corporation, Shanghai (CN)

(21) Appl. No.: 14/460,363

(22) Filed: Aug. 15, 2014

(30) Foreign Application Priority Data
Aug. 1, 2014 (CN) 201410378165.2

(51) Int. Cl. H03F 1/56; H03F 3/21

(52) U.S. Cl. CPC H03F 1/565; H03F 3/211; H03F 2203/21103; H03F 2203/21124

(57) ABSTRACT

A power amplifier comprises a first inductor, a second inductor, a capacitor, a first MOS transistor, a second MOS transistor and a current source. The first and the second inductors are both connected to a first power supply. The first inductor and the second inductor form a differential inductor. The capacitor is connected to the first inductor at a first terminal of and to the second inductor at a second terminal. A drain of the first MOS transistor is connected to the first terminal of the capacitor. A drain of the second MOS transistor is connected to the second terminal of the capacitor. A first terminal of the current source is connected to sources of both the first and the second MOS transistors. A second terminal of the current source is connected to a second power supply. The current source outputs a variable current based on a bias voltage input.

### CLAIM OF PRIORITY

This application claims priority to Chinese Application No. 201410378165.2 entitled “Power amplifier, and Method of the same,” filed on Aug. 1, 2014 by Beken Corporation, which is incorporated herein by reference.

### TECHNICAL FIELD

The present application relates to circuits, and more particularly but not exclusively to a power amplifier and a method of the same.

### BACKGROUND

In a conventional non-linear power amplifier, a cascode structure can be used wherein a group of MOS transistors are connected between the input and the output of the power amplifier to provide isolation between the input and the output. However, as the group of MOS transistors is arranged in the signal path, in other words, between the input and the output, it will restrict maximum output power of the power amplifier and introduce a resistive element in signal path which reduces the efficiency of the power amplifier. Therefore, a power amplifier with improved efficiency and maximum output power may be desirable.

### SUMMARY OF THE INVENTION

According to an embodiment of the present invention, a power amplifier comprises a first inductor, a second inductor, a capacitor, a first MOS transistor, a second MOS transistor and a current source. The first inductor and the second inductor are both connected to a first power supply. The first inductor and the second inductor form a differential inductor. A first terminal of the capacitor is connected to the first inductor and a second terminal of the capacitor is connected to the second inductor. A drain of the first MOS transistor is connected to the first terminal of the capacitor. A drain of the second MOS transistor is connected to the second terminal of the capacitor. A first terminal of the current source is connected to sources of both the first MOS transistor and the second MOS transistor. A second terminal of the current source is connected to a second power supply. The current source provides a variable current based on a bias voltage input.

According to another embodiment of the present invention, a method comprises receiving differential input voltage by a first MOS transistor and a second MOS transistor, wherein a drain of the first MOS transistor is connected to a first terminal of a capacitor, and a drain of the second MOS transistor is connected to a second terminal of the capacitor; generating a high impedance at resonant frequency by a first inductor, a second inductor and the capacitor, wherein a first terminal of the capacitor is connected to the first inductor and a second terminal of the capacitor is connected to the second inductor, the first inductor and the second inductor are both connected to a first power supply, and the first inductor and the second inductor form a differential inductor; and feeding a bias current by a current source to the first MOS transistor and the second MOS transistor based on a bias voltage input, wherein a first terminal of the current source is connected to sources of both the first MOS transistor and the second MOS transistor, and a second terminal of the current source is connected to a second power supply.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a circuit diagram illustrating an embodiment of a power amplifier.

FIG. 2 is a circuit diagram illustrating another embodiment of a power amplifier.

FIG. 3 is a circuit diagram illustrating another embodiment of a power amplifier.

FIG. 4 is a circuit diagram illustrating another embodiment of a power amplifier.

FIG. 5 is a flow chart illustrating an embodiment of a method.

### DETAILED DESCRIPTION OF THE ILLUSTRATED EMBODIMENTS

Various aspects and examples of the invention will now be described. The following description provides specific details for a thorough understanding and enabling description of these examples. Those having ordinary skill in the art will understand, however, that the invention may be practiced without many of these details. Additionally, some well-known structures or functions may not be shown or described in detail, so as to avoid unnecessarily obscuring the relevant description.

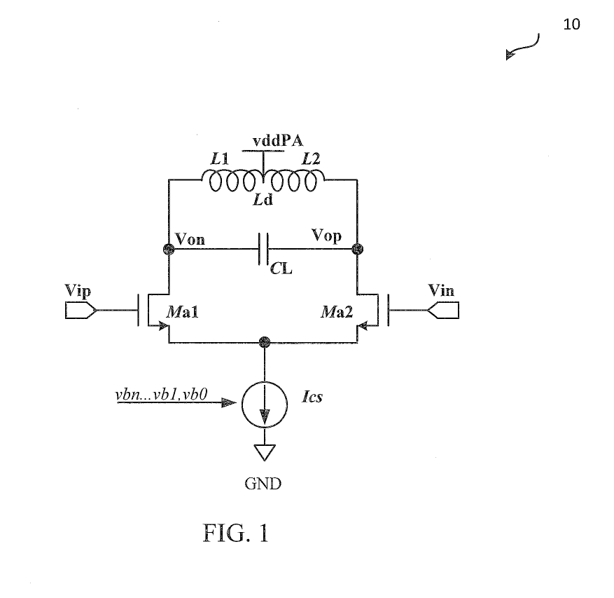

FIG. 1 is a circuit diagram illustrating an embodiment of a power amplifier 10. The power amplifier 10 comprises a first inductor L1, a second inductor L2, a capacitor CL, a first MOS transistor Ma1, a second MOS transistor Ma2, and a current source Ics. In FIG. 1, the first MOS transistor Ma1 and the second MOS transistor Ma2 comprise NMOS transistors. The first inductor L1 and the second inductor L2 are both connected to a first power supply. The first power supply comprises positive supply voltage (Vdd) shown as VddPA. The first inductor L1 and the second inductor L2 form a differential inductor Ld. The first inductor L1 and the second inductor L2 have the same amplitude but are of opposite phases. A first terminal of the capacitor CL is connected to the first inductor L1 and a second terminal of the capacitor CL is connected to the second inductor L2.

A drain of the first MOS transistor Mal is connected to the first terminal of the capacitor CL. A drain of the second MOS transistor Ma2 is connected to the second terminal of the capacitor CL. A first terminal of the current source Ics is connected to sources of both the first MOS transistor Mal and the second MOS transistor Ma2. A second terminal of the current source Ics is connected to a second power supply. In FIG. 1, the second power supply comprises ground (GND). The current source provides a variable current based on a bias voltage input vb0, vb1, . . . vbn. In additional vb0 to vbn can be switched to a biasing voltage generated by a biasing circuit to turn on the corresponding current source. Alternatively they can be switched to ground to shut down the corresponding current source.

Alternatively, a gate of the first MOS transistor Mal receives a positive voltage input Vip of a differential input signal. A gate of the second MOS transistor Ma2 receives a negative voltage input Vin of a differential input signal. A first terminal of the capacitor CL outputs a negative voltage Von. A second terminal of the capacitor outputs a positive voltage Vop.

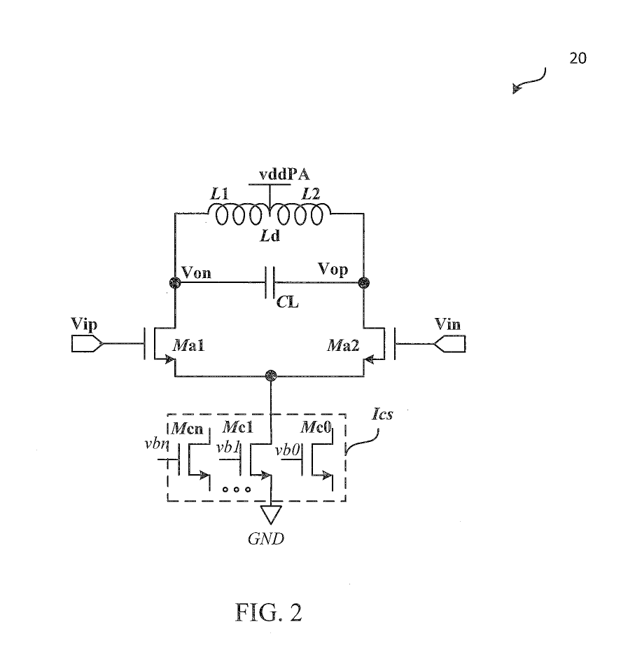

FIG. 2 is a circuit diagram illustrating another embodiment of a power amplifier 20. Details are omitted for elements already described with respect to FIG. 1. As shown in FIG. 2, current source Ics comprises an array of current source MOS transistors Mcn, Mcn-1 . . . Mc0. A drain of each current source MOS transistors Mcn, Mcn-1 . . . Mc0 is connected to sources of both the first MOS transistor Mal and the second MOS transistor Ma2. A source of each current source MOS transistors Mcn, Mcn-1 . . . Mc0 are connected to the second power supply GND. A gate of each current source MOS transistor Mcn, Mcn-1 . . . Mc0 is controlled to connect to either the bias voltage input or to the second power supply GND. Note that in FIG. 2, each of current source MOS transistors Mcn, Mcn-1 . . . Mc0 is connected to a corresponding bias voltage input vbn, vbn-1, vbn-2, . . . vb1,vb0. To be specific, a first current source MOS transistor Mc0 is controlled by vb0. A second current source MOS transistor Mc1 is controlled by vb1. A third current source MOS transistor Mc2 is controlled by vb2. A nth current source MOS transistor Mcn-1 is controlled by vbn-1. A (n+1)th current source MOS transistor Men is controlled by vbn. Alternatively, for the ease of control, the bias voltage input vbn, vbn-1, vbn-2, . . . vb1, vb0 are equal. When the gate of a current source transistor is connected to the bias voltage input, it contributes a bias current to the power amplifier 20. However, when the gate of a current source transistor is connected to ground, there is no current passing through this current source transistor, thus it does not contribute any bias current to the power amplifier 20. Therefore a bias current provided by the current source Ics is equivalent to the sum of currents of the current source transistors with its gate connected to the bias voltage input. Also note that the each current source transistor is controlled independently by a respective bias voltage input. For example, a MCU can be used to implement controlling the current source transistors. Each bit output of the MCU corresponds to a current source. When a nth bit of MCU outputs 1, the corresponding vbn is fed to a gate of the (n+1)th current source transistor. When a nth bit of MCU outputs 0, the gate of the (n+1)th current source transistor is connected to ground. In this way, an accurate output power of the power amplifier can be achieved.

Referring back to FIG. 1, during operation, the first MOS transistor and the second MOS transistor operate as switches. The first MOS transistor Mal and the second MOS transistor Ma2 are driven by the differential inputs Vip and Vin. Current is provided by the current source to the first MOS transistor Mal and the second MOS transistor Ma2. The first MOS transistor Mal and the second MOS transistor Ma2 are alternatively on and alternatively provide current from the current source to the load CL. That means, when the first MOS transistor Mal is on, the second MOS transistor Ma2 is off, and when the first MOS transistor Mal is off, the second MOS transistor Ma2 is on. Further, current passing through the first MOS transistor Mal and the second MOS transistor Ma2 are controlled by the current source Ics. Further the first and the second inductor L1, L2 with the capacitor CL resonate at the operation frequency which provide a high impedance to drive the current to the load with high efficiency.

Alternatively, the array of current source MOS transistors may be arranged by size in a binary order. A size of a MOS transistor comprises width/length (W/L) ratio. In large-scale MOS process, the length of all the MOS may be set to a same value; therefore the width of the MOS transistors determines the width/length ratio. An example of the current source MOS transistors arranged by size in the binary order is that a width/length (WM) of the first current source transistor Mc0 is 1, a width/length (W/L) of the second current source transistor Mc1 is 2, a width/length (W/L) of a third current source transistor Mc2 is 4, etc.

Alternatively, the plurality of MOS transistors may be arranged by size in a log-linear order, or in other words, linear-in-dB. For example, a width/length (W/L) of the first current source transistor Mc0 is 1, a width/length (W/L) of the second current source transistor Mc1 is 1.1, a width/length (WM) of a third current source transistor Mc2 is 1.21, a width/length (WM) of a fourth current source transistor Mc3 is 1.331, etc.

Alternatively, although not shown in the drawings, the power amplifier may further comprise a plurality of single-pole double-throw switches arranged between each of the bias voltage input vb0, vb1, vbn and the gate of a corresponding current source NMOS transistor. Each of the single-pole double-throw switches controls a corresponding current source MOS transistor connected to either the bias voltage input or to the second power supply. For example, the single-pole double-throw switch is a changeover switch, and the single-pole double-throw either connects gate of the current source MOS transistors to the bias voltage input, or connects gate of the current source MOS transistors to the second power supply, i.e, the ground terminal.

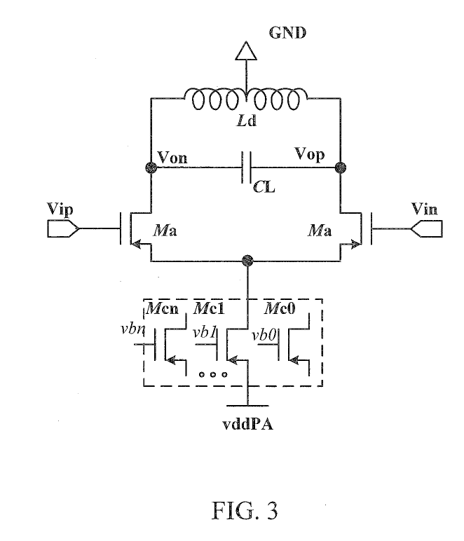

As shown in FIGS. 1 and 2, both the first and the second MOS transistors comprise NMOS transistors. FIG. 3 is a circuit diagram illustrating another embodiment of a power amplifier. Alternatively, as shown in FIG. 3, the first and the second MOS transistors comprise PMOS transistors. Further, the first power supply comprises ground GND. The second power supply comprises a positive power supply vddPA. Further, the current source MOS transistor comprises PMOS transistor, and the second power supply comprises positive supply voltage (Vdd). Details are omitted for elements already described with respect to FIGS. 1 and 2.

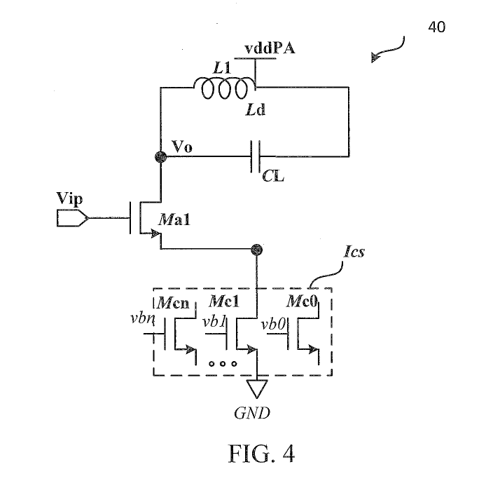

The power amplifiers 10 and 20 shown in FIGS. 1 and 2 respectively employ differential inputs and outputs. Alternatively, FIG. 4 is a circuit diagram illustrating another embodiment of a power amplifier. A power amplifier 40 shown in FIG. 4 comprises an inductor L1, a capacitor CL, a MOS transistor Ma1, and a current source Ics. The inductor L1 is connected to a first power supply. As shown in FIG. 4, the first power supply comprises a positive power supply VddPA. The MOS transistor Ma1 comprises a NMOS transistor. A first terminal of the capacitor CL is connected to the inductor Ld. A second terminal of the capacitor is connected to the first power supply vddPA. A drain of the MOS transistor Ma1 is connected to the first terminal of the capacitor CL. A first terminal of the current source Ics is connected to source of the MOS transistor Ma1. A second terminal of the current source Ics is connected to a second power supply. As shown in FIG. 4, the second power supply comprises ground (GND). The current source provides a variable current based on a bias voltage input. In FIG. 4, all of the MOS transistor Ma1 and the current source MOS transistors Mc0, Mc1, . . . Mcn are NMOS transistors. Those having ordinary skill in the art should understand that all of the MOS transistor Ma1 and the current source MOS transistors Mc0, Mc1 . . . Mcn may be PMOS transistors, similar to the circuits shown in FIG. 2.

In the embodiments of the power amplifier shown in FIGS. 1-4, since there are no cascode MOS transistors between the first MOS transistor Ma1 and the output Von, there is few if any voltage margin loss, or in other words, voltage drop, which means power amplifiers shown in any of FIGS. 1-4 have a high efficiency. Further, the structure is suitable to work under low voltage.

Further, referring back to any of FIG. 1, 2 or 3, although in the power amplifier circuit, both the first MOS transistor Ma1 and the second Ma2 are connected to the current source, the above differential amplifying MOS transistors alternate to be on. That means, when the first MOS transistor Ma1 is on, the second MOS transistor Ma2 is off, and when the first MOS transistor Ma1 is off, the second MOS transistor Ma2 is on. Further, currents passing through the first MOS transistor and the second MOS transistor are controlled by the current source Ics. The MOS transistors Ma1 and Ma2 can be easily switched on/off, which decreases driven load of its previous stage circuit. As MOS transistors Ma1 and Ma2 only need to switch the current provided by the current source, and do not need to provide current as conventional MOS transistors in power amplifier (PA) do, the size of the MOS transistors Ma1 and Ma2 in the embodiments can be reduced, thus leading to a smaller load to its previous stage circuit. Therefore, the efficiency of the transmitter that includes the power amplifier increases.

Further, the maximum current capacity outputted by the example power amplifier can be easily regulated, thus adjusting the output power of the power amplifier, by adjusting the biasing current outputted by the current source.

Further, with a sufficient previous stage drive, the MOS transistors Ma1 and Ma2 can pump substantially all the current from the current source Ics to load. Therefore the output power is proportional to the current provided by the current source. An accurate output power adjustment step can be obtained by controlling a current outputted by the current source to increase linearly.

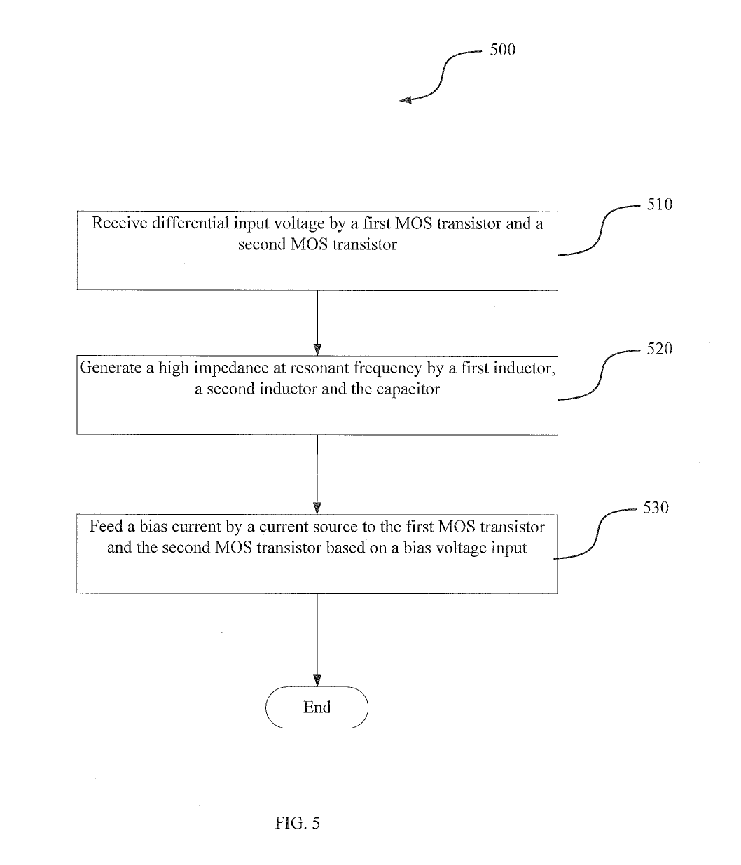

FIG. 5 is a flow chart illustrating an embodiment of a method 500. The method 500 comprises receiving in block 510 differential input voltage by a first MOS transistor and a second MOS transistor, wherein a drain of the first MOS transistor is connected to a first terminal of a capacitor, and a drain of the second MOS transistor is connected to a second terminal of the capacitor; generating, in block 520, a high impedance at resonant frequency by a first inductor, a second inductor and the capacitor, wherein a first terminal of the capacitor is connected to the first inductor and a second terminal of the capacitor is connected to the second inductor, the first inductor and the second inductor are both connected to a first power supply, and the first inductor and the second inductor form a differential inductor; and feeding, in block 530, a bias current by a current source to the first MOS transistor and the second MOS transistor based on a bias voltage input, wherein a first terminal of the current source is connected to sources of both the first MOS transistor and the second MOS transistor, and a second terminal of the current source is connected to a second power supply.

Alternatively, although not shown in FIG. 5, the method 500 further comprises receiving a positive voltage input, by a gate of the first MOS transistor; receive a negative voltage input, by a gate of the second MOS transistor; outputting a negative voltage by a first terminal of the capacitor, and outputting a positive voltage by a second terminal of the capacitor.

Alternatively, the current source comprises a plurality of current source MOS transistors, wherein a drain of each current source MOS transistors are connected to sources of both the first MOS transistor and the second MOS transistor; a source of each current source MOS transistors are connected to the second power supply, and a gate of each current source MOS transistor is controlled to be connected to either the bias voltage input or to the second power supply.

Alternatively, the plurality of current source MOS transistor are arranged by size in a binary order.

Alternatively, the plurality of current source MOS transistor are arranged by size in a log-linear order.

Alternatively, the method 500 further comprising controlling a corresponding current source MOS transistor connected to either the bias voltage input or to the second power supply.

Note that any and all of the embodiments described above can be combined with each other, except to the extent that it may be stated otherwise above or to the extent that any such embodiments might be mutually exclusive in function and/or structure.

Although the present invention has been described with reference to specific exemplary embodiments, it will be recognized that the invention is not limited to the embodiments described, but can be practiced with modification and alteration within the spirit and scope of the appended claims. Accordingly, the specification and drawings are to be regarded in an illustrative sense rather than a restrictive sense. Accordingly, the invention is not limited except as by the appended claims.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. Even if certain features are recited in different dependent claims, the present invention also relates to an embodiment comprising these features in common. Any reference signs in the claims should not be construed as limiting the scope.

What is claimed is:

1. A power amplifier comprising:
a first inductor and a second inductor both connected to a first power supply, the first inductor and the second inductor forming a differential inductor;
a capacitor, wherein a first terminal of the capacitor is connected to the first inductor and a second terminal of the capacitor is connected to the second inductor;
a first MOS transistor, wherein a drain of the first MOS transistor is connected to the first terminal of the capacitor;
a second MOS transistor, wherein a drain of the second MOS transistor is connected to the second terminal of the capacitor;
a current source, wherein a first terminal of the current source is connected to sources of both the first MOS transistor and the second MOS transistor, and a second terminal of the current source is connected to a second power supply, and the current source is configured to provide a variable current based on a bias voltage input.

2. The power amplifier of claim 1, wherein a gate of the first MOS transistor is configured to receive a positive voltage input, a gate of the second MOS transistor is configured to receive a negative voltage input, and a first terminal of the capacitor is configured to output a negative voltage, and a second terminal of the capacitor is configured to output a positive voltage.

3. The power amplifier of claim 1, wherein the current source comprises a plurality of current source MOS transistors, wherein a drain of each current source MOS transistors are connected to sources of both the first MOS transistor and the second MOS transistor; a source of each current source MOS transistors are connected to the second power supply, and a gate of each current source MOS transistor is controlled to be connected to either the bias voltage input or to the second power supply.

4. The power amplifier of claim 1, wherein the first and the second MOS transistors comprise NMOS transistors, and the first power supply comprises positive supply voltage (Vdd).

5. The power amplifier of claim 4, wherein the current source MOS transistors comprise NMOS transistors, and the second power supply comprises ground.

6. The power amplifier of claim 1, wherein the first and the second MOS transistors comprise PMOS transistors, and the first power supply comprises ground.

7. The power amplifier of claim 6, wherein the current source MOS transistor comprises PMOS transistor, and the second power supply comprises positive supply voltage (Vdd).

8. The power amplifier of claim 3,
wherein the plurality of current source MOS transistors are arranged by size in a binary order.

9. The power amplifier of claim 3, wherein the plurality of current source MOS transistors are arranged by size in a log-linear order.

10. The power amplifier of claim 3, further comprising a plurality of single-pole double-throw switches arranged between the bias voltage input and the gate of the current source NMOS transistor configured to control a corresponding current source MOS transistor connected to either the bias voltage input or to the second power supply.

11. A power amplifier comprising:
an inductor connected to a first power supply;
a capacitor, wherein a first terminal of the capacitor is connected to the inductor and a second terminal of the capacitor is connected to the first power supply;
a MOS transistor, wherein a drain of the MOS transistor is connected to the first terminal of the capacitor;
a current source, wherein a first terminal of the current source is connected to source of the MOS transistor, and a second terminal of the current source is connected to a second power supply, and the current source is configured to provide a variable current based on a bias voltage input.

12. A method comprising:
receiving a differential input voltage by a first MOS transistor and a second MOS transistor, wherein a drain of the first MOS transistor is connected to a first terminal of a capacitor, and a drain of the second MOS transistor is connected to a second terminal of the capacitor;
generating a high impedance at resonant frequency by a first inductor, a second inductor and the capacitor, wherein a first terminal of the capacitor is connected to the first inductor and a second terminal of the capacitor is connected to the second inductor, the first inductor and the second inductor are both connected to a first power supply, and the first inductor and the second inductor form a differential inductor; and
feeding a bias current by a current source to the first MOS transistor and the second MOS transistor based on a bias voltage input, wherein a first terminal of the current source is connected to sources of both the first MOS transistor and the second MOS transistor, and a second terminal of the current source is connected to a second power supply.

13. The method of claim 12, further comprising:
receiving a positive voltage input, by a gate of the first MOS transistor;
receive a negative voltage input, by a gate of the second MOS transistor;
outputting a negative voltage by a first terminal of the capacitor, and
outputting a positive voltage by a second terminal of the capacitor.

14. The method of claim 12, wherein the current source comprises a plurality of current source MOS transistors, wherein a drain of each current source MOS transistors are connected to sources of both the first MOS transistor and the second MOS transistor; a source of each current source MOS transistors are connected to the second power supply, and a gate of each current source MOS transistor is controlled to be connected to either the bias voltage input or to the second power supply.

15. The method of claim 14,
wherein the plurality of current source MOS transistor are arranged by size in a binary order.

16. The method of claim 14,
wherein the plurality of current source MOS transistor are arranged by size in a log-linear order.

17. The method of claim 14, further comprising controlling a corresponding current source MOS transistor connected to either the bias voltage input or to the second power supply.
